(19) United States
(12) Patent Application Publication
(10) Pub. No.: US 2026/0313816 A1
(43) Pub. Date: Oct. 8, 2026

(54) EXPLOSION-PROOF PROTECTIVE CASE

(71) Applicant: The Joy Factory, Inc., Irvine, CA (US)

(72) Inventors: Wei-Chung WANG, New Taipei City (TW); Chia-Wei Chang, New Taipei City (TW); Yun-Chang Tsui, New Taipei City (TW); Sampson Yang, Irvine, CA (US)

(21) Appl. No.: 19/298,473

(22) Filed: Aug. 13, 2025

Related U.S. Application Data
(60) Provisional application No. 63/738,913, filed on Dec. 26, 2024.

(30) Foreign Application Priority Data
Mar. 17, 2025 (TW) 114202627

(51) Int. Cl. H05K 5/03; G06F 1/16; H04M 1/02

(52) U.S. Cl. CPC H05K 5/03; G06F 1/1629; H04M 1/0203

(57) ABSTRACT

An explosion-proof protective case for an electronic device with side buttons includes a first shell, a second shell, and a push back button/key. The second shell has a button slot aligned with the device's side button and a perforation through its second coupling part, with a first open end connected to the button slot and a second open end on the outer wall. The push back button/key has a pressing portion in the button slot and a push rod in the perforation, partially exposed at the second open end. The perforation's length equals the second coupling part's cross-sectional dimension.

### CROSS REFERENCE TO RELATED APPLICATIONS

This application claims priority of Application No. 114202627 filed in Taiwan on Mar. 17, 2025 under 35 U.S.C. § 119 and U.S. Provisional Application No. 63/738913 filed on Dec. 26, 2024 under 35 U.S.C. § 119(e), the entire contents of all of which are hereby incorporated by reference.

### FIELD OF THE INVENTION

The present invention relates to the field of protective cases, particularly to a protective case suitable for electronic devices.

### BACKGROUND OF THE INVENTION

In today's technologically advanced society, electronic devices are widely used across various industries. However, in special or harsh industrial environments, extreme conditions such as high temperatures, low temperatures, rain, dirt, dust, mud, snow, and humidity may cause malfunctions in electronic devices. Additionally, electronic devices may be damaged due to improper use (e.g., dropping). Therefore, it is necessary to use specially designed protective cases to store/accommodate and safeguard electronic devices, preventing damage from severe environmental conditions or improper handling, thereby assisting users in completing their tasks or missions.

On the other hand, when electronic devices housed within a protective case operate under hazardous location conditions, particularly in environments containing flammable gases or dust, unforeseen circumstances may cause the device to generate sparks or explosions. If the device triggers a spark or explosion, the resulting gas pressure and flames may cause the protective case to rupture, potentially injuring the user and even initiating a large-scale explosion within the hazardous environment, thereby posing serious industrial safety risks.

In order to overcome the drawbacks of the conventional technologies, it is important to provide an explosion-proof protective case that complies with regulatory standards, and also prevents harm to users or personnel working in hazardous environments, and avoids serious industrial safety incidents.

### SUMMARY OF THE INVENTION

The present invention provides an explosion-proof protective case applicable for storing electronic devices, which can prevent the case from rupturing when the housed electronic device generates sparks or explodes under hazardous location conditions, and which can effectively reduce or block the leakage of explosive gases or flames from the explosion-proof case.

In accordance with an aspect of the present invention, an explosion-proof protective case is provided. The explosion-proof protective case has an accommodation space for storing an electronic device, comprising: a first shell, a second shell, and a push back button/key push back button/key. The first shell is circumferentially provided with a first coupling part. The second shell is circumferentially provided with a second coupling part for coupling with the first coupling part. The second coupling part has a perforation having a first open end and a second open end opposite each other, wherein the second open end is located on an outer wall surface of the second shell. The second shell further comprises a button slot, with the first open end connected to the button slot. The push back button/key includes a pressing portion and a push rod connecting to the pressing portion. The pressing portion is disposed in the button slot, and the push rod is disposed within the perforation, with an end of the push rod away from the pressing portion partially exposed at the second open end. The linear distance along a first direction between the first and second open ends is equal to the cross-sectional dimension of the second coupling part along the same direction.

In accordance with another aspect of the present invention, an explosion-proof protective case is provided. The explosion-proof protective case has an accommodation space for storing an electronic device. The explosion-proof case includes: a first shell, a second shell, an explosion-proof bolt, and an anti-open gate plate. The first shell is circumferentially provided with a first coupling part; the second shell is circumferentially provided with a second coupling part for coupling with the first coupling part. The second shell includes a threaded through hole penetrating the second coupling part. The explosion-proof bolt has a rotary gripping portion and a rotary shaft disposed along the axis of the rotary gripping portion. The rotary shaft includes: a first shaft portion that can be screwed into the threaded through hole, and a second shaft portion connecting the rotary gripping portion and the first shaft portion. The anti-open gate plate is disposed on one side of the threaded through hole and includes a first end portion and a second end portion. The first end portion is pivotally connected to the second coupling part to allow the anti-open gate plate to rotate relative to the second coupling part. The second end portion, facing the explosion-proof bolt, includes a latching recess corresponding to the second shaft portion. When the first shaft portion is screwed into the threaded through hole to a locked position, the latching recess interferes with and engages the second shaft portion by snapping into place.

In accordance with a further aspect of the present invention, an explosion-proof protective case is provided. The explosion-proof protective case having an accommodation space for storing an electronic device. The explosion-proof case includes a first shell and a second shell. The first shell is circumferentially provided with a first coupling part, and the inner wall surface of the first coupling part is provided with an annular wall section having a first contoured surface. The second shell is circumferentially provided with a second coupling part for coupling with the first coupling part, and the inner wall surface of the second coupling part is provided with an annular block section having a second contoured surface corresponding to the first contoured surface. When the first and second coupling parts are joined, a curved explosion-proof path is formed between the first and second contoured surfaces.

In accordance with an additional aspect of the present invention, an explosion-proof protective case is provided. The explosion-proof protective case having an accommodation space for storing an electronic device, wherein the electronic device includes a button. The explosion-proof case includes: a first shell, a second shell, and a push back button/key. The first shell is circumferentially provided with a first coupling part; the second shell is circumferentially provided with a second coupling part for coupling with the first coupling part. The second coupling part includes a perforation with opposing first and second open ends, where the second open end is located on an outer wall surface of the second shell. The second shell further includes a button slot corresponding to the button, and the first open end is connected to the button slot. The push back button/key includes a pressing portion and a push rod connecting to the pressing portion. The pressing portion is disposed in the button slot and configured to push the button; the push rod is disposed in the through hole, and the end of the push rod away from the pressing portion is partially exposed at the second open end. The pressing portion includes a pressing bump that abuts the surface of the button, and the orthographic projected area of the press protrusion is smaller than that of the button.

In accordance with one more aspect of the present invention, an explosion-proof protective case is provided. The present invention additionally provides still another explosion-proof protective case having an accommodation space for storing an electronic device, wherein the electronic device includes a button. The explosion-proof case includes: a first shell, a second shell, and a push back button/key. The first shell is circumferentially provided with a first coupling part; the second shell is circumferentially provided with a second coupling part for coupling with the first coupling part. The second coupling part includes a perforation with opposing first and second open ends, where the second open end is located on an outer wall surface of the second shell. The second shell further includes a button slot corresponding to the button, with the first open end connected to the button slot. The push back button/key includes a pressing portion and a push rod connecting to the pressing portion. The pressing portion is disposed in the button slot and configured to press the button. The push rod is disposed within the through hole, with the end of the push rod away from the pressing portion partially exposed at the second open end. The push back button/key includes a non-metallic pad disposed between the pressing portion and the button, allowing the pressing portion to press the button via the non-metallic pad.

The advantageous effects of the present invention lie in that the provided explosion-proof protective case, through the design of a specialized push back button/key, curved explosion-proof path, and arrangement or filling of composite filler, can effectively reduce or block the explosive gases and flames generated during an explosion of the electronic device, thereby achieving a buffering effect against explosions. On the other hand, in addition to being equipped with a rotary gripping portion for easy user operation, the explosion-proof bolt is also provided with an anti-open gate plate on one side of the threaded through hole and corresponding to the explosion-proof bolt. The anti-open gate plate not only prevents unintended loosening or detachment of the explosion-proof bolt but also allows users to visually confirm whether the explosion-proof bolt is in a locked state, thus ensuring the operational safety and stability of the electronic device housed within the explosion-proof case.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1A is a perspective view of the explosion-proof protective case according to the present invention.

FIG. 1B is an exploded perspective view of the explosion-proof protective case according to the present invention.

FIG. 2A is a cross-sectional view of a first embodiment taken along line A-A′ of FIG. 1A.

FIG. 2B is a cross-sectional view of the push back button/key and button slot according to the present invention.

FIG. 3 is an operational schematic view of the push back button/key shown in FIG. 2B.

FIG. 4A is a cross-sectional view of a second embodiment taken along line A-A′ of FIG. 1A.

FIG. 4B is a cross-sectional view of a third embodiment taken along line A-A′ of FIG. 1A.

FIG. 5A is a partial exploded perspective view of the explosion-proof protective case from one viewing angle according to the present invention.

FIG. 5B is a partial exploded perspective view of the explosion-proof bolt and anti-open gate plate from another viewing angle according to the present invention.

FIGS. 6A and 6B are schematic views illustrating the operation of the anti-open gate plate according to the present invention.

FIG. 7 is a schematic view illustrating the composite filler filled in the explosion-proof protective case according to the present invention.

FIGS. 8A and 9A are partial exploded perspective views of the explosion-proof protective case according to the present invention.

FIG. 8B is a side perspective view of a first embodiment of the push back button/key according to the present invention.

FIG. 8C is a projection view of the push back button/key in a first embodiment along its moving direction.

FIG. 8D is a projection view of the push back button/key in a second embodiment along its moving direction.

FIG. 9B is a side perspective view of a second embodiment of the push back button/key according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

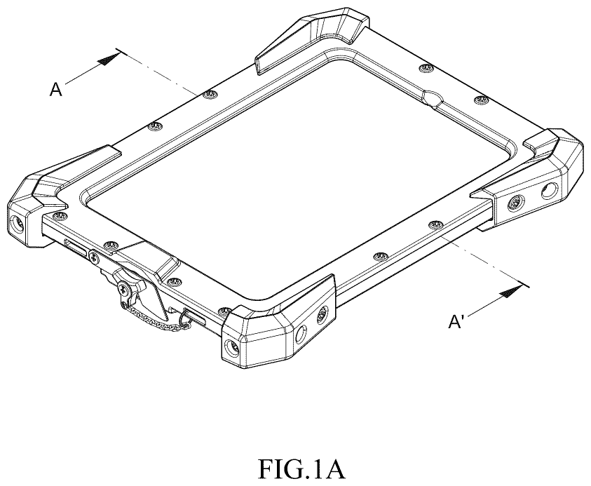

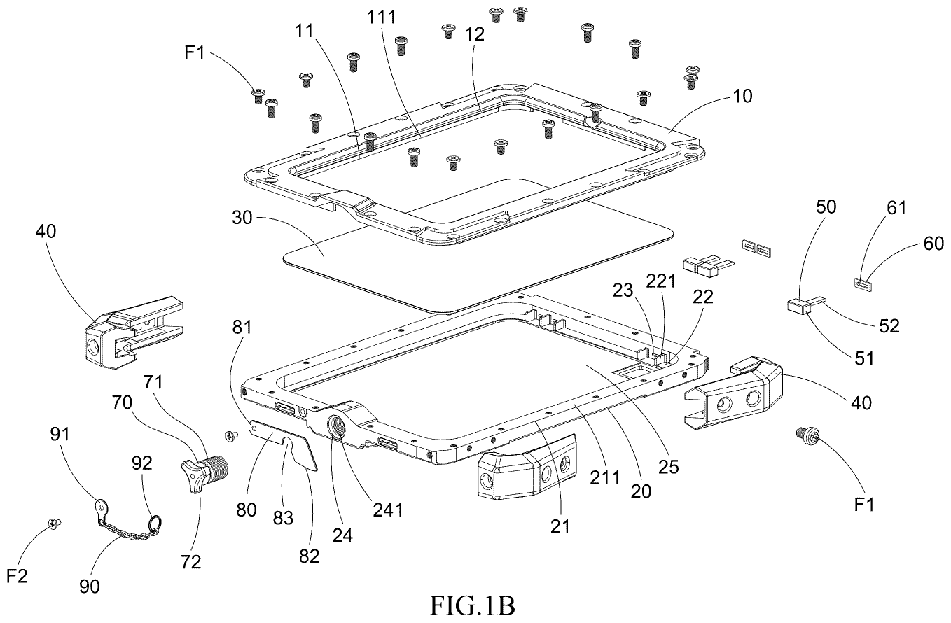

Please refer to FIGS. 1A and 1B, the present invention provides an explosion-proof protective case 1, which is configured to accommodate an electronic device (not shown in the figures). The electronic device may be, for example, a tablet computer or a smartphone, and includes a touch panel, a rear surface opposite to the touch panel, and a side surface located between the touch panel and the rear surface. Typically, one or more buttons are disposed on the side surface, along with at least one electrical interface. The electrical interface may include, but is not limited to: USB-A, Micro-USB, Lightning, or USB-C.

The explosion-proof protective case 1 includes: a first shell 10, a second shell 20, a transparent plate 30, an impact-resistant clamping mechanism 40, a push back button/key 50, an elastomer 60, explosion-proof bolt 70, an anti-open gate plate 80, a lanyard 90, and fastening members F1 and F2

The first shell 10 includes a first coupling part 11 and a frame opening 12. The first coupling part 11 is disposed on the side of the first shell 10 facing the second shell 20 and is arranged around the frame opening 12. In the present embodiment, the inner wall surface of the first coupling part 11 is provided with an annular wall section 111. The transparent plate 30 is secured to the frame opening 12 in ways of engagement, embedding, adhesion, or other suitable methods. Thus, the user may access to the electronic device through the transparent plate 30 when the electronic device is accommodated within the explosion-proof protective case 1.

The second shell 20 includes a second coupling part 21, one or more button slots 22, one or more perforation 23, a threaded through hole 24, and a frame recess 25. The second coupling part 21 is circumferentially disposed on the side of the second shell 20 facing the first shell 10 and is arranged around the frame recess 25. In the present embodiment, the inner wall surface of the second coupling part 21 is provided with an annular block section 211. The button slot(s) 22, disposed within the frame recess 25 and adjacent to the second coupling part 21, are corresponding to one or more buttons located on the side surface of the electronic device. In the present embodiment, the button slot 22 is formed by a plurality of partition structures 221. In alternative embodiments, a hollowed recess formed on the sidewall of the frame recess 25 adjacent to the second coupling part 21 may serve as the button slot 22. The perforation(s) 23 are formed within the second coupling part 21 and penetrate through the second shell 20. One open end of each perforation 23 corresponds to the outer wall surface of the second shell 20, and the other open end corresponds to the button slot 22.

The threaded through hole 24 also penetrates through the second coupling part 21 and corresponds to the electrical interface located on the side surface of the electronic device. In the present embodiment, the inner surface of the threaded through hole 24 is provided with an internal thread structure 241.

The first coupling part 11 of the first shell 10 may be engaged with the second coupling part 21 of the second shell 20. In the present embodiment, a plurality of fastening members F1 may be threadably engaged in a plurality of locking holes formed on the first coupling part 11 and the second coupling part 21, thereby coupling the first shell 10 and the second shell 20. The impact-resistant clamping mechanism 40 may simultaneously clamp and further secure the first shell 10 and the second shell 20 together. In this embodiment, a plurality of fastening members F1 may also be used to fasten the impact-resistant clamping mechanism 40 to the four corners of the first shell 10 and the second shell 20.

The push back button/key 50 includes a pressing portion 51 and a push rod 52 connected thereto. The pressing portion 51 is disposed within the button slot 22, while the push rod 52 is disposed within the perforation 23. An elastomer 60 is positioned between the pressing portion 51 of the push back button/key 50 and the inner wall surface of the button slot 22 where the perforation 23 is formed. In the present embodiment, an opening 61 formed in the elastomer 60 allows the elastomer 60 to be sleeved onto the push rod 52.

An explosion-proof bolt 70 is threadedly mounted within the threaded through hole 24. The explosion-proof bolt 70 includes a rotary shaft 71 and a rotary gripping portion 72, wherein the rotary shaft 71 is disposed coaxially with the rotary gripping portion 72.

An anti-open gate plate 80 is disposed on one side of the threaded through hole 24 and includes: a first end portion 81, a second end portion 82, and a latching recess 83. The first end portion 81 is opposite to the second end portion 82, and the first end portion 81 is pivotally connected to the second coupling part 21 of the second shell 20, thereby allowing the anti-open gate plate 80 to rotate relative to the second coupling part 21. In the present embodiment, a fastening member F2 is inserted through the first end portion 81 to pivotally connect it to the second coupling part 21. The latching recess 83 is disposed on the side of the second end portion 82 facing the explosion-proof bolt 70 and corresponds to the rotary shaft 71 of the explosion-proof bolt 70.

The lanyard 90 includes an opposing first locking end 91 and a second locking end 92. The first locking end 91 is pivotally connected to the rotary gripping portion 72 of the explosion-proof bolt 70, thereby preventing the lanyard 90 from twisting or tangling during the rotation of the explosion-proof bolt 70. The second locking end 92 is fixed to the second coupling part 21 of the second shell 20. In certain alternative embodiments, the second locking end 92 may be fixed at any suitable position on the first shell 10 or the second shell 20, and is not limited to the configuration described in the present embodiment.

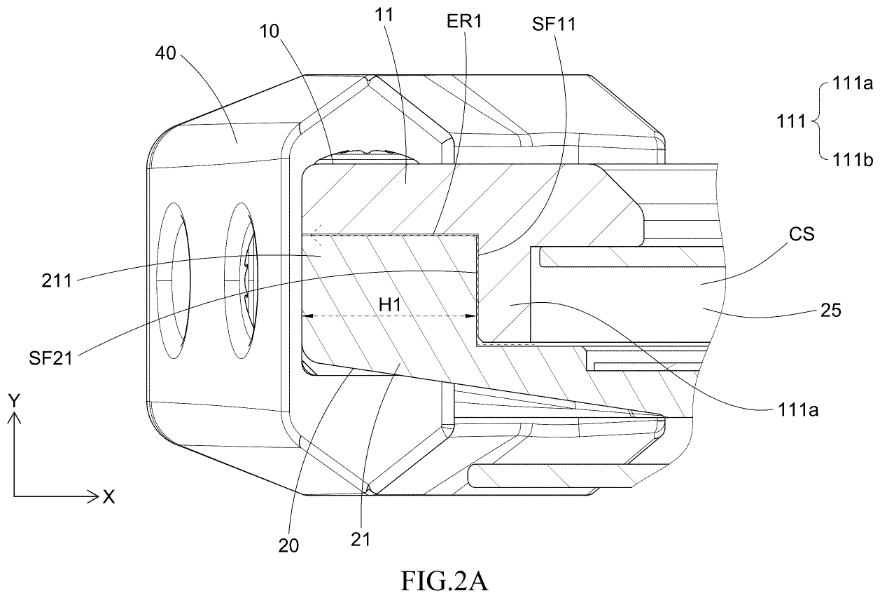

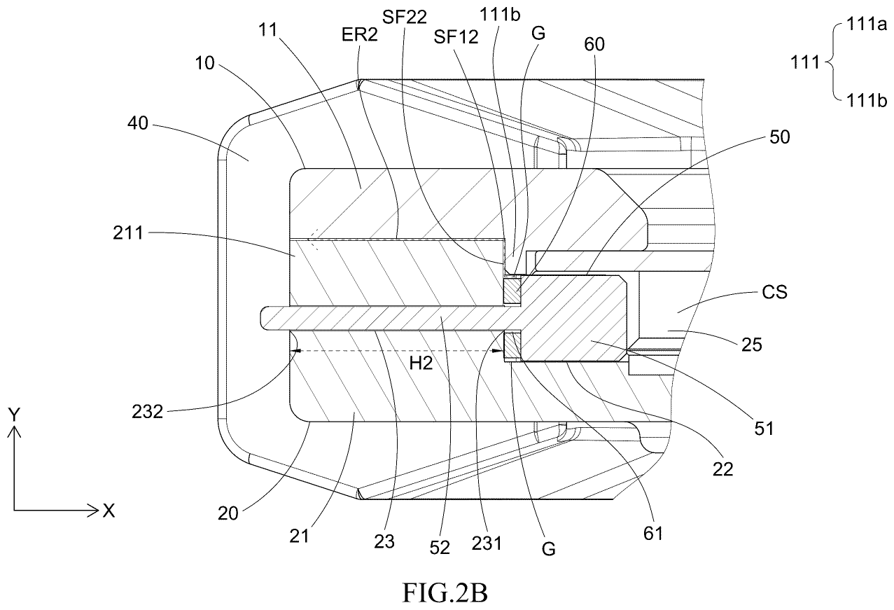

Please Refer to FIGS. 1A, 1B, 2A, and 2B, for illustrative convenience, the X-axis is defined as a first direction, and the Y-axis is defined as a second direction, which is perpendicular to the first direction. The wall section 111 disposed on the inner wall surface of the first coupling part 11 includes wall sections 111a (as shown in FIGS. 2A) and 111b (as shown in FIG. 2B), which are respectively formed with first contoured surface SF11 and SF12. The block section 211 disposed on the inner wall surface of the second coupling part 21 includes second contoured surface SF21 (as shown in FIG. 2A) and SF22 (as shown in FIG. 2B), which correspond to the first contoured surface SF11 and SF12.

When the first coupling part 11 of the first shell 10 is engaged with the second coupling part 21 of the second shell 20, the frame recess 25 of the first shell 10 together with the second shell 20 define and form an accommodating space CS for accommodating/storing an electronic device (not shown). Although the present embodiment illustrates a configuration in which the first shell 10 has a frame opening 12 and the second shell 20 has a frame recess 25, in practical applications, the frame opening may alternatively be formed on the second shell 20, and the frame recess may be formed on the first shell 10, or opposing frame recesses may be formed on both the first shell 10 and the second shell 20 to define the accommodating space CS. Accordingly, the invention is not limited to the configuration disclosed in this embodiment.

On the other hand, when the first coupling part 11 is engaged with the second coupling part 21, the wall sections 111a and 111b interlock with the block section 211, thereby forming curved explosion-proof paths ER1 (as shown in FIG. 2A) and ER2 (as shown in FIG. 2B) between the first contoured surface SF11, SF12 and the second contoured surface SF21, SF22. Accordingly, in the event that the electronic device accommodated within the accommodating space CS generates a spark or explosion due to unforeseen circumstances, the curved explosion-proof paths ER1 and ER2 serve to reduce the pressure of explosive gases and prevent the leakage of flames when such gases or flames enter the curved explosion-proof paths ER1 and ER2, thereby achieving an explosion-mitigating effect. In the present embodiment, the cross-sectional dimension H1 of the block section 211 along the first direction is between 6 mm and 16 mm.

Please refer again to FIG. 2B, the perforation 23 penetrates the second coupling part 21 of the second shell 20 and includes opposing first and second open ends 231 and 232, respectively. The first open end 231 is connected to the button slot 22, while the second open end 232 is located on the outer wall surface of the second shell 20. In the present embodiment, the linear distance H2 between the first open end 231 and the second open end 232 in the first direction ranges from 6 mm to 16 mm. The push back button/key 50 includes a pressing portion 51 disposed within the button slot 22 and is slidable back and forth in the first direction therein. The push rod 52 is disposed within the perforation 23, and the end of the push rod 52 distant from the pressing portion 51 is partially exposed at the second open end 232 for user operation. Accordingly, a user may press the exposed push rod 52 at the second open end 232 to drive the pressing portion 51 to slide in the first direction, thereby pressing a button disposed on the side of the electronic device.

Furthermore, an elastomer 60 is arranged between the pressing portion 51 of the push back button/key 50 and the inner wall surface of the button slot 22 where the first open end 231 is located. In the present embodiment, the elastomer 60 includes an opening 61 that is tightly sleeved around the push rod 52. This design helps prevent external moisture, water, or dust from entering the button slot 22 and the accommodating space CS via the perforation 23. Additionally, the elastomer 60 forms at least one gap G between the inner wall surfaces of the first shell 10 and the second shell 20. Specifically, in this embodiment, a gap G is formed between one side of the elastomer 60 along the second direction and the wall section 111b of the first shell 10, and another gap G is formed between the opposite side of the elastomer 60 along the second direction and the button slot 22 of the second shell 20. These gaps G between the elastomer 60 and the housings 10 and 20 are connected to the curved explosion-proof paths ER2.

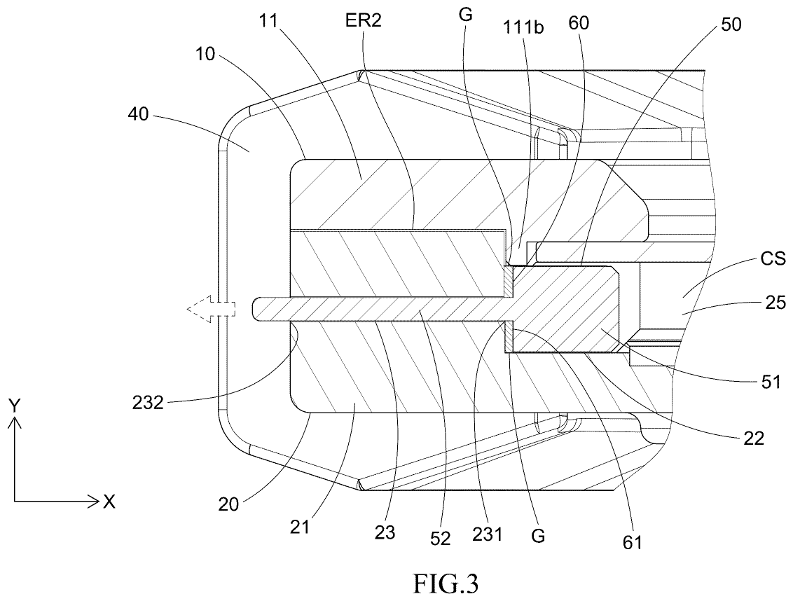

Please refer to FIG. 3, In cases that the electronic device accommodated within the accommodating space CS generates sparks or explosions due to unexpected events, the pressing portion 51 is first propelled by the pressure of the explosive gases along the first direction and then compresses the elastomer 60. The compressed elastomer 60 then deforms to expand along the second direction. This results in the elastomer 60 deforming and expanding along the second direction. Consequently, the deformation of the elastomer 60 fills the gaps G between itself and the housings 10 and 20, thereby quickly blocking or preventing the leakage of explosive gases or flames through the gaps G. Subsequently, any explosive gases or flames leaking out of the gaps G may enter the curved explosion-proof paths ER2 and the perforation 23. The bent structure of the curved explosion-proof paths ER2 further reduces the pressure of the leaked gases and blocks the flames, thereby achieving a buffering effect against explosions. Moreover, due to the relatively long linear distance H2 of the perforation 23 (as shown in FIG. 2B), it also aids in dissipating the explosive gases or flames. In this embodiment, the compressible amount of the elastomer 60 is between 0.2 mm and 0.5 mm.

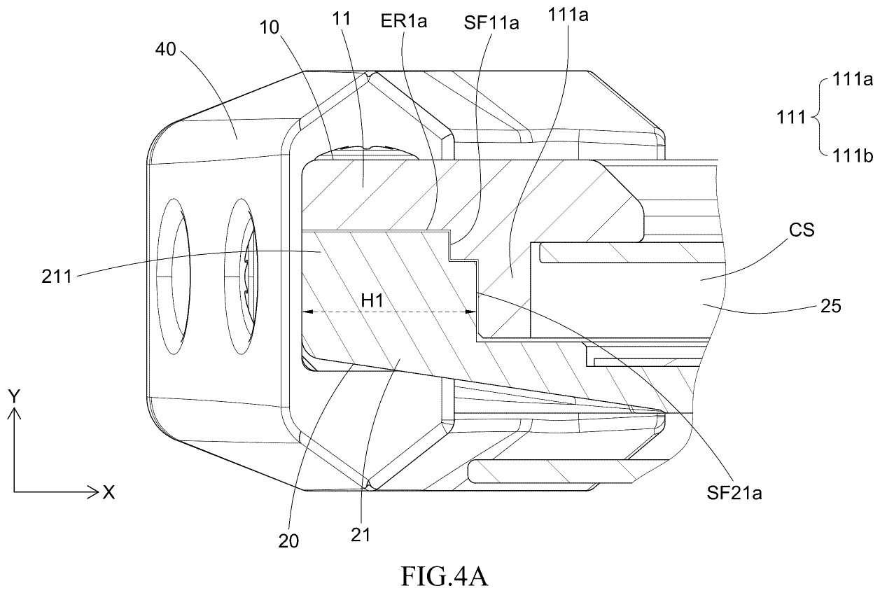

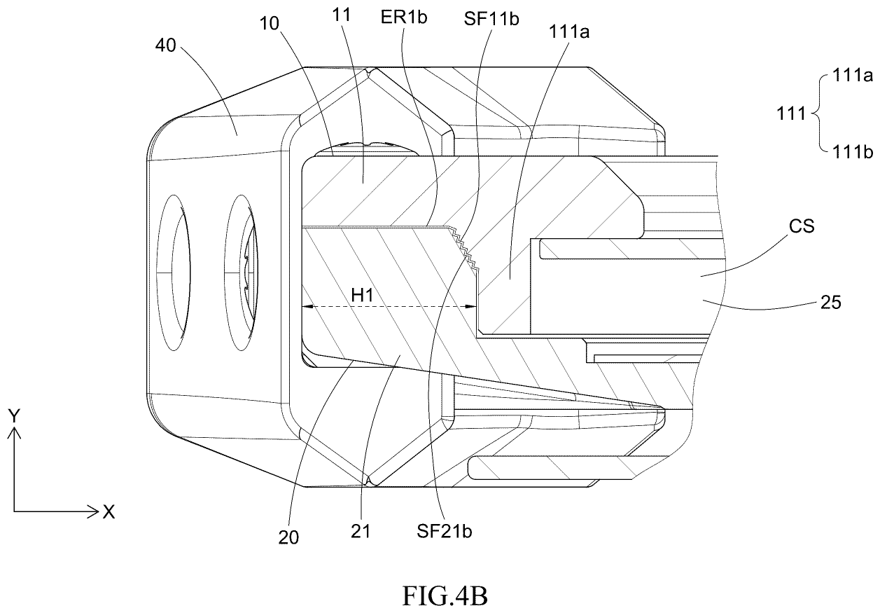

Please refer to FIGS. 4A and 4B, in FIG. 4A, the structure and function of each component are the same as those in FIG. 2A and will not be redundantly described. However, the difference lies in that the wall section 111a of the first coupling part 11 includes a concave, two-step staircase-shaped first contoured surface SF11a, while the block section 211 of the second coupling part 21 includes a convex, two-step staircase-shaped second contoured surface SF21a. When the wall section 111a and the block section 211 are joined together, a cross-sectional, two-stepped-shaped explosion-proof path ER1a is formed between the first contoured surface SF11a and the second contoured surface SF21a.

In FIG. 4B, the structure and function of each component are also the same as in FIG. 4A and will not be redundantly described. However, the difference lies in that the wall section 111a of the first coupling part 11 includes a concave, sawtooth-shaped first contoured surface SF11b, while the block section 211 of the second coupling part 21 includes a convex, sawtooth-shaped second contoured surface SF21b. When the wall section 111a and the block section 211 are joined together, a cross-sectional, serrated-shape explosion-proof path ER1b is formed between the first contoured surface SF11b and the second contoured surface SF21b. Although the above embodiments only describe explosion-proof paths ER1a and ER1b having stepped-shape or serrated-shape cross sections, in practical applications, the curved explosion-proof paths may also take on wavy-shape or other arbitrarily bent shapes depending on the contour variations of the first and second contoured surfaces, and are not limited to the embodiments disclosed herein.

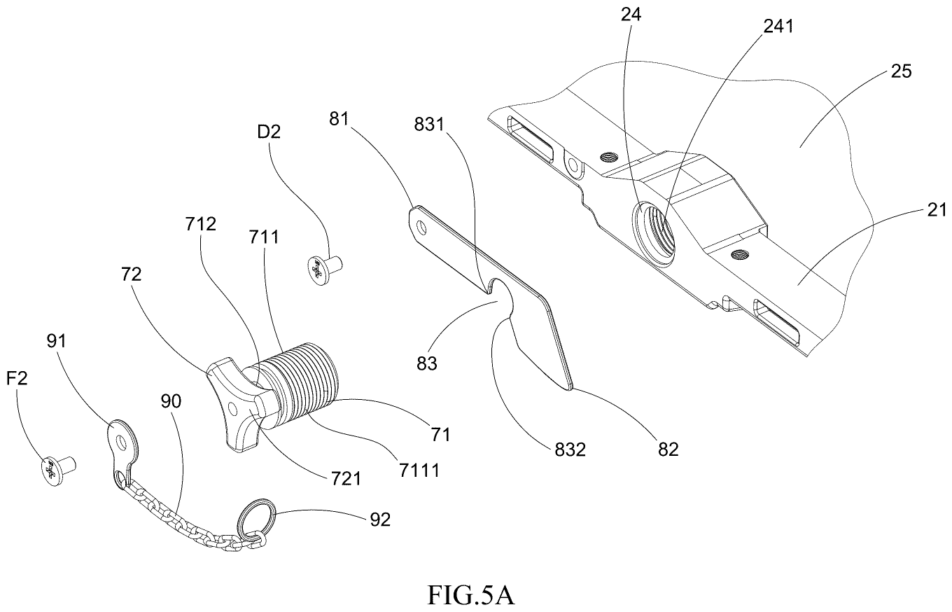

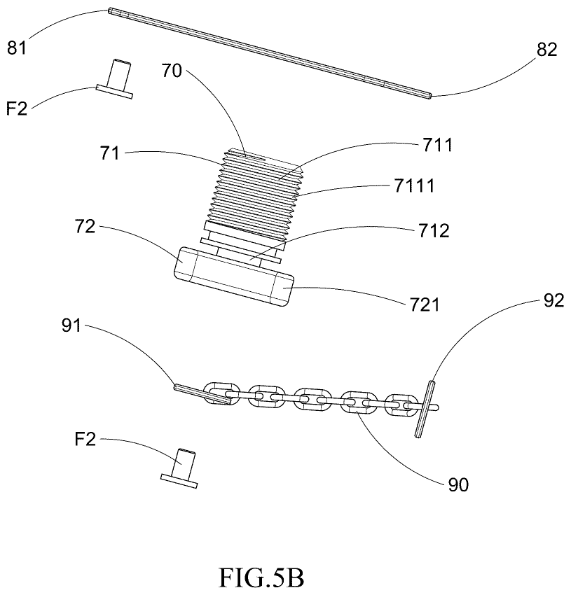

Please refer to FIGS. 5A and 5B. The rotary shaft 71 of the explosion-proof bolt 70 includes a first rotary shaft portion 711 and a second shaft portion 712 that are connected. The first rotary shaft portion 711 is provided with an external thread structure 7111 corresponding to the internal thread structure 241 of the threaded through hole 24, such that the explosion-proof bolt 70 may be threadedly engaged in the threaded through hole 24 via the first rotary shaft portion 711. The second shaft portion 712 connects the rotary gripping portion 72 to the first rotary shaft portion 711, and the diameter of the first rotary shaft portion 711 is greater than that of the second shaft portion 712.

In this embodiment, the rotary gripping portion 72 further includes three symmetrically arranged radial lever structures 721. Due to the relatively large recessed space between any two adjacent radial lever structures 721, even a user wearing thick work gloves can easily apply force to actuate the radial lever structures 721, thereby rotating the explosion-proof bolt 70 via the radial lever structures 721. Although this embodiment discloses a configuration in which three symmetrically arranged radial lever structures 721 are provided, in practical applications, the number of radial levers 721 may be two or more, and the levers may be symmetrically or asymmetrically arranged to radially extend from the axis of the rotary gripping portion 72. The design is not limited to the embodiment described herein.

The latching recess 83 of the anti-open gate plate 80 is disposed on the side of the second end portion 82 that faces the explosion-proof bolt 70. The latching recess 83 corresponds in shape and size to the second shaft portion 712, and the inner diameter of the latching recess 83 is approximately equal to the outer diameter of the second shaft portion 712. Additionally, at least one of the two end points 831 and 832 at the open end of the latching recess 83 has an interference with the second shaft portion 712, wherein the interference amount ranges between 0.1 mm and 0.5 mm, and preferably about 0.2 mm.

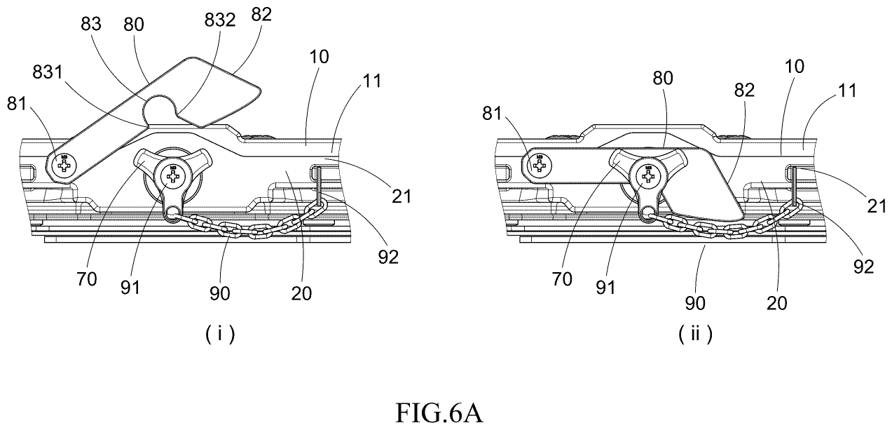

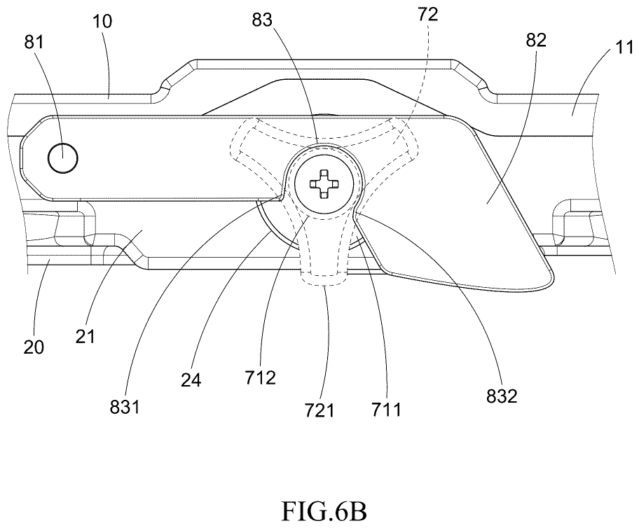

Please refer to FIGS. 6A and 6B. When the first rotary shaft portion 711 is screwed into the threaded through hole 24 to a locked position (for example, when the radial cross-section of the connecting region between the first rotary shaft portion 711 and the second shaft portion 712 is flush with the outer wall surface of the second coupling part 21, or when the first rotary shaft portion 711 is completely embedded within the threaded through hole 24), at least one of the two end points 831 and 832 of the latching recess 83 can interfere with the second shaft portion 712 and be forcibly inserted and engaged therewith.

Please refer to the right part (ii) of FIG. 6A. When the anti-open gate plate 80 is engaged with the explosion-proof bolt 70, the user can visually and intuitively determine whether the explosion-proof bolt 70 has reached its locked position by observing the engagement state between the anti-open gate plate 80 and the second shaft portion 712. Furthermore, since the diameter of the first rotary shaft portion 711 is greater than that of the second shaft portion 712, when the anti-open gate plate 80 is engaged with the second shaft portion 712, the anti-open gate plate 80 can abut against the first rotary shaft portion 711 along the axial direction of the rotary shaft 71, thereby preventing the user from unscrewing the explosion-proof bolt 70 in the reverse direction and also preventing the explosion-proof bolt 70 from loosening or falling off. This anti-open gate plate 80 provides a dual protection mechanism by both engaging the explosion-proof bolt 70 and preventing its unintentional loosening, while also allowing users to visually verify the locking status of the explosion-proof bolt 70.

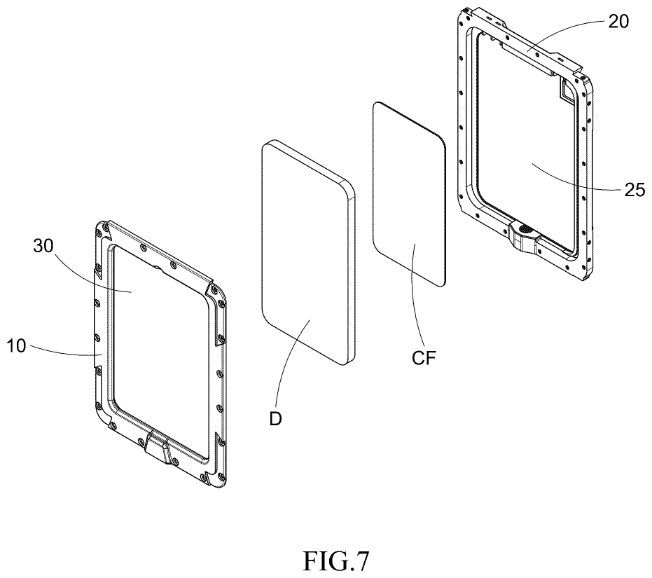

Please refer to FIG. 7. To enhance the explosion-proof performance of the explosion-proof protective case 1, a composite filler CF may further be disposed within the accommodating space CS of the explosion-proof protective case 1 (as shown in FIG. 2A). In this embodiment, the composite filler CF is in the form of a plate and may be pre-placed within the frame recess 25 of the second shell 20 such that the composite filler CF is arranged between the rear surface of the electronic device D and the inner surface of the second shell 20 of the explosion-proof protective case 1. When the electronic device D is placed within the accommodating space CS or inside the frame recess 25, the composite filler CF is compressed by the electronic device D and substantially fills gaps between the electronic device D and the accommodating space CS or the frame recess 25. In this way, as the gaps between the electronic device D and the accommodating space CS (or the frame recess 25) is substantially filled by the composite filler CF, in the event of sparks or an explosion caused by the electronic device D due to unforeseen reasons, the internal volume of combustible gas is significantly reduced, thus allowing the composite filler CF to mitigate the explosion energy, buffer the impact, and further reduce the flow of explosive gases within the accommodating space CS.

In some possible embodiments, the composite filler CF may be a solid elastomer or an elastomer having irregularly arranged high-density pores. The irregular high-density pores not only enhance the compressibility of the composite filler CF, but also serve to obstruct the flow of explosive gases. In this embodiment, the compressible amount of the composite filler ranges from 5% to 50%, and in a preferred embodiment, from 25% to 35%. Although the present embodiment describes the composite filler CF as a plate-shaped structure, in actual applications, the composite filler CF may also be an annular elastomer configured to surround the side surfaces of the electronic device D, thereby covering the sides and optionally a portion of the touchscreen panel or rear surface of the electronic device D. Alternatively, the composite filler CF may be a foam material that cures upon exposure to air, which can be sprayed into the gaps between the electronic device D and the accommodating space CS (or frame recess 25) by the user. These alternatives are not limited to the implementation disclosed herein.

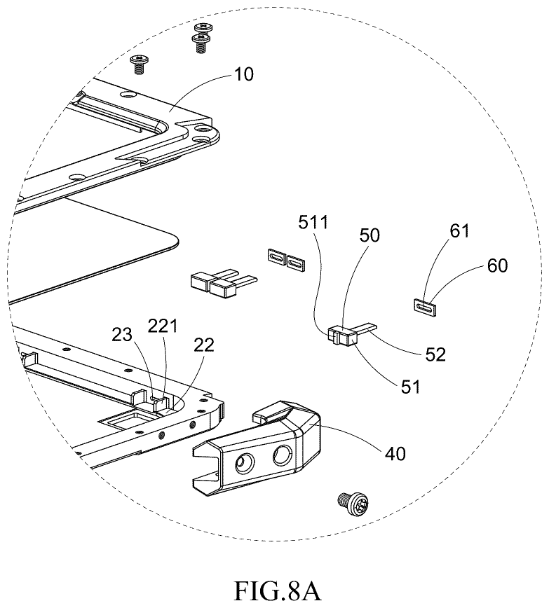

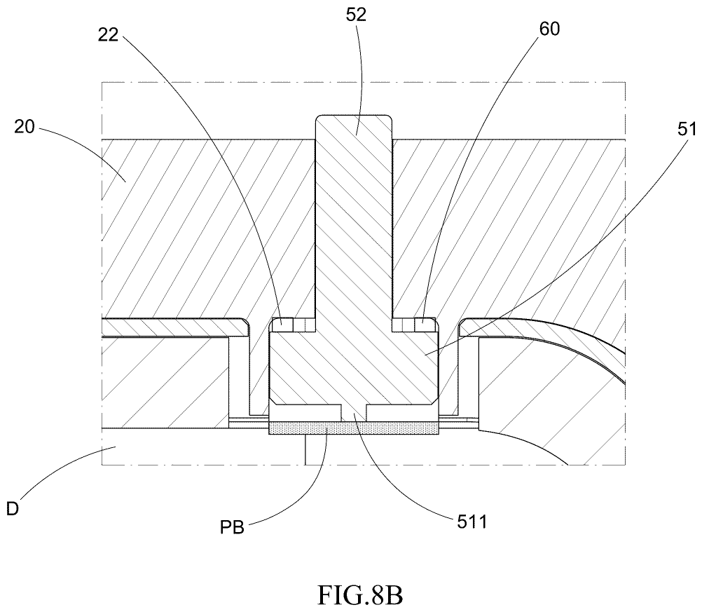

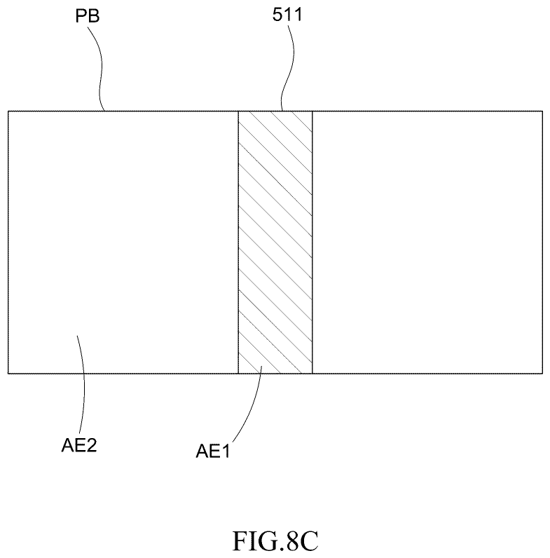

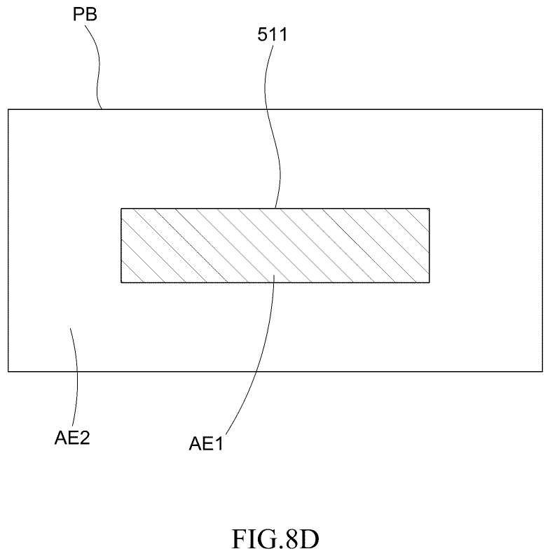

Please refer to FIG. 8A to 8D. In FIG. 8A, the structural elements and functions of the first shell 10, button slot 22, perforation 23, clamping mechanism 40, push back button/key 50, and elastomer 60 are the same as those shown in FIG. 1B, and are not repeated herein. The difference lies in the pressing portion 51 of the push back button/key 50, which includes a three-dimensional protruding pressing bump 511 on the side away from the push rod 52 (see FIG. 8A), and the pressing bump 511 is abutted against the surface of a button PB of the electronic device D (see FIG. 8B). The button PB is a capacitive fingerprint recognition button.

Please refer to FIG. 8C. The pressing bump 511 of the push back button/key 50 has an orthographic projection area AE1 along the actuation direction of the push back button/key 50, while the button PB has an orthographic projection area AE2 in the same direction. The orthographic projection area AE1 of the pressing bump 511 is smaller than the orthographic projection area AE2 of the button PB. In this way, when the push back button/key 50 is actuated to press the button PB via the pressing bump 511, the contact area between the pressing portion 51 and the button PB is smaller due to the reduced area AE1, thereby reducing the conduction of static electricity from the push back button/key 50 to the button PB. This helps to avoid malfunctions of the button PB in fingerprint recognition caused by electrostatic interference, and improves the usability and operability of the explosion-proof protective case 1.

In this embodiment, the pressing bump 511 is a vertically arranged three-dimensional raised structure. As such, its orthographic projection area AE1 is perpendicular to the long edge of the orthographic projection area AE2 of the button PB. The orthographic projection area AE1 of the pressing bump 511 is between 5% and 30% of the orthographic projection area AE2 of the button PB, and in a preferred embodiment, the orthographic projection area AE1 is 10% of the orthographic projection area AE2.

Please refer to FIG. 8D. Similar to FIG. 8C, the orthographic projection area AE1 of the pressing bump 511 is smaller than the orthographic projection area AE2 of the button PB. The difference is that the pressing bump 511 in FIG. 8D is arranged horizontally, such that its orthographic projection area AE1 is parallel to the long edge of the orthographic projection area AE2 of the button PB. Although only a single horizontal or vertical rectangular prism structure of the pressing bump 511 is presented in the embodiments above, in actual applications, the pressing bump 511 may be any three-dimensional shape or composed of multiple separated raised structures. Regardless of its shape or structure, the total orthographic projection area of the pressing bump should fall between 5% and 30% of the orthographic projection area AE2 of the button PB.

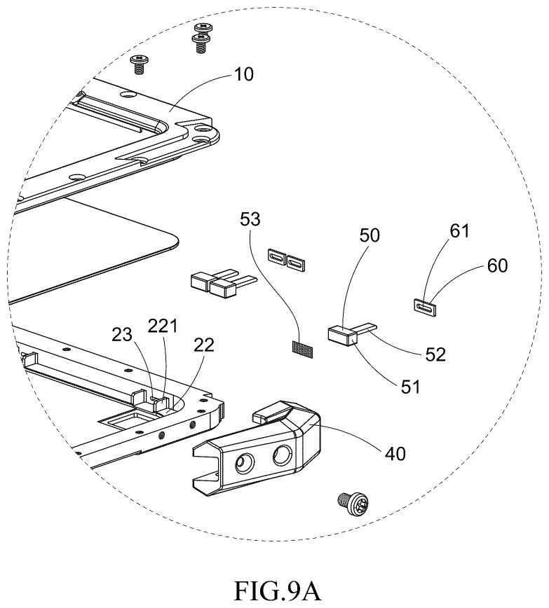

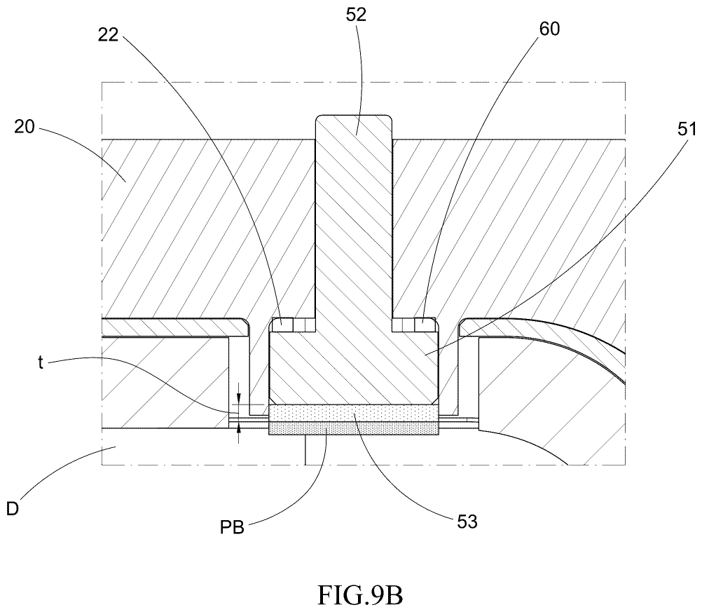

Please refer to FIGS. 9A and 9B. In FIG. 9A, the structures and functions of the first shell 10, button slot 22, perforation 23, clamping mechanism 40, push back button/key 50, and elastomer 60 are the same as those shown in FIG. 8A, and will not be repeated herein. The difference lies in that the push back button/key 50 further includes a non-metallic pad 53. The non-metallic pad 53 is disposed between the pressing portion 51 and the button PB, and has a thickness t. The button PB is also a capacitive fingerprint recognition button.

As shown in FIG. 9B, when the push back button/key 50 is actuated, the pressing portion 51 can press the button PB via the non-metallic pad 53. The thickness t of the non-metallic pad 53 reduces the conduction of static electricity from the push back button/key 50 to the button PB, thereby avoiding fingerprint recognition malfunctions caused by electrostatic interference and enhancing the usability of the explosion-proof protective case 1.

In this embodiment, the material of the non-metallic pad 53 may be a thermosetting rubber, thermoplastic rubber, or rubber sheet, and may fully or partially cover the button PB. The thickness t of the non-metallic pad 53 ranges from 0.5 mm to 10 mm, and in a preferred embodiment, the thickness t is 1 mm.

Compared to prior technologies, the explosion-proof protective case 1 provided by the present invention effectively reduces or blocks explosive gases and flames generated during an explosion of the electronic device by means of a specially designed push back button/key 50, curved explosion-proof paths ER1 and ER2, and the configuration or filling of the composite filler CF, thereby achieving an explosion buffering effect.

On the other hand, in addition to being provided with the rotary gripping portion 72 of the explosion-proof bolt 70 for facilitating user operation, the explosion-proof protective case 1 also equipped with the anti-open gate plate 80 disposed on one side of the threaded through hole 24 and corresponding to the explosion-proof bolt 70. The anti-open gate plate 80 not only prevents unintentional opening or loosening of the explosion-proof bolt 70, but also allows the user to visually confirm whether the explosion-proof bolt 70 is in a locked state. This ensures the operational safety and stability of the electronic device disposed within the explosion-proof protective case 1. Therefore, the present invention is of significant industrial value.

While the invention has been described in terms of what is presently considered to be the most practical and preferred embodiments, it is to be understood that the invention need not be limited to the disclosed embodiments. On the contrary, it is intended to cover various modifications and similar arrangements included within the spirit and scope of the appended claims, which are to be accorded the broadest interpretation so as to encompass all such modifications and similar structures.

What is claimed is:

1. An explosion-proof protective case comprising an accommodating space for storing an electronic device, the explosion-proof protective case comprising:
a first shell having a first coupling part circumferentially disposed on the first shell;
a second shell having a second coupling part circumferentially disposed on the second shell, the second coupling part being configured to couple with the first coupling part, the second coupling part having at least one perforation, the at least one perforation having a first open end and a second open end, wherein the first open end and the second open end are opposing each other, the second open end being located on an outer wall surface of the second shell, the second shell further comprising:
at least one button slot, the first open end being connected to the at least one button slot; and
a push back button/key having a pressing portion and a push rod connecting to the pressing portion, the pressing portion being disposed in the at least one button slot, the push rod being disposed in the perforation, wherein an end of the push rod away from the pressing portion is partially exposed at the second open end;
wherein a linear distance along a first direction between the first open end and the second open end is equal to a cross-sectional dimension along the first direction of the second coupling part.

2. The explosion-proof protective case according to claim 1, wherein the linear distance is between 6 mm and 16 mm.

3. The explosion-proof protective case according to claim 1, further comprising at least one elastomer, the at least one elastomer being disposed between the pressing portion and the inner wall surface corresponding to the first open end of the at least one button slot.

4. The explosion-proof protective case according to claim 3, wherein at least one gap is formed between the at least one elastomer and inner wall surfaces of the first shell and the second shell, wherein a compressible amount of the at least one elastomer is in a range from 0.2 mm to 0.5 mm.

5. The explosion-proof protective case according to claim 1, further comprising a composite filler, the composite filler being disposed within the accommodating space to fill gaps between the electronic device and the accommodating space, wherein a compressible amount of the composite filler is between 5% and 50%.

6. The explosion-proof protective case according to claim 1, wherein the first shell or the second shell has a transparent panel through which a user operates the electronic device.

7. An explosion-proof protective case having an accommodating space for storing an electronic device, the explosion-proof protective case comprising:
a first shell having a first coupling part circumferentially disposed on the first shell;
a second shell having a second coupling part circumferentially disposed on the second shell and a threaded through hole penetrating the second coupling part, wherein the second coupling part is coupled with the first coupling part;
an explosion-proof bolt having a rotary gripping portion and a rotary shaft disposed along an axis of the rotary gripping portion, wherein the rotary shaft comprises:
a first shaft portion screwed into the threaded through hole; and
a second shaft portion connecting the rotary gripping portion and the first shaft portion; and
an anti-open gate plate disposed on one side of the threaded through hole, comprising:
a first end portion pivotally connected to the second coupling part for rotating relative to the second coupling part; and
a second end portion having a latching recess on the side facing the explosion-proof bolt, the latching recess being aligned with the second shaft portion;
wherein, when the first shaft portion is screwed into the threaded through hole to a locked position, the latching recess interferes with the second shaft portion and is forcibly engaged and latched onto the second shaft portion.

8. The explosion-proof protective case according to claim 7, wherein a diameter of the first shaft portion is greater than a diameter of the second shaft portion.

9. The explosion-proof protective case according to claim 7, wherein an open end of the latching recess has two end points, and an interference amount between at least one of the two end points and the second shaft portion is between 0.1 mm and 0.5 mm.

10. The explosion-proof protective case according to claim 7, wherein the rotary gripping portion has at least two radial lever structures extending outward from the axis.

11. The explosion-proof protective case according to claim 7, further comprising a lanyard having a first locking end and a second locking end, wherein the first locking end and the second locking end are opposite each other, the first locking end being pivotally connected to the rotary gripping portion, and the second locking end being fixed to the first shell or the second shell.

12. An explosion-proof protective case having an accommodating space for storing an electronic device, the explosion-proof protective case comprising:
a first shell having a first coupling part circumferentially disposed on the first shell, wherein an inner wall surface of the first coupling part includes a wall section having a first contoured surface; and
a second shell having a second coupling part circumferentially disposed on the second shell, the second coupling part being configured to couple with the first coupling part, wherein an inner wall surface of the second coupling part includes a block section having a second contoured surface corresponding to the first contoured surface;
wherein, when the first coupling part and the second coupling part are engaged, a curved explosion-proof path is formed between the first contoured surface and the second contoured surface.

13. The explosion-proof protective case according to claim 12, wherein a cross-sectional shape of the curved explosion-proof paths is a stepped-shape, a serrated-shape or a wavy-shape.

14. The explosion-proof protective case according to claim 12, wherein a cross-sectional dimension along a first direction of the block section is between 6 mm and 16 mm.

15. An explosion-proof protective case having an accommodating space for storing an electronic device, the electronic device having at least one button, the explosion-proof protective case comprising:
a first shell having a first coupling part circumferentially disposed on the first shell;
a second shell having a second coupling part circumferentially disposed on the second shell, the second coupling part being configured to couple with the first coupling part, the second coupling part having at least one perforation, and the at least one perforation having a first open end and second open end, wherein the first open end and the second open end are opposing each other, the second open end being located on an outer wall surface of the second shell, the second shell further comprising:
at least one button slot corresponding to the at least one button, wherein the first open end is connected to the at least one button slot; and
a push back button/key having a pressing portion and a push rod connecting to the pressing portion, the pressing portion being disposed in the at least one button slot and configured to press the at least one button, the push rod being disposed in the perforation, wherein an end of the push rod away from the pressing portion is partially exposed at the second open end;
wherein the pressing portion has at least one pressing bump against a surface of the at least one button, and an orthographic projected area of the at least one pressing bump is smaller than an orthographic projected area of the at least one button.

16. The explosion-proof protective case according to claim 15, wherein an orthographic projection area of the at least one pressing bump is between 5% and 30% of an orthographic projection area of the at least one button.

17. An explosion-proof protective case having an accommodating space for
storing an electronic device, the electronic device having at least one button, the explosion-proof protective case comprising:
a first shell having a first coupling part circumferentially disposed on the first shell;
a second shell having a second coupling part circumferentially disposed on the second shell, the second coupling part being configured to couple with the first coupling part, the second coupling part having at least one perforation, and the at least one perforation having a first open end and a second open end, wherein the first open end and the second open end are opposing each other, the second open end being located on an outer wall surface of the second shell, the second shell further comprising:
at least one button slot corresponding to the at least one button, wherein the first open end is connected to the at least one button slot; and
a push back button/key having a pressing portion and a push rod connecting to the pressing portion, the pressing portion being disposed in the at least one button slot and configured to press the at least one button, the push rod being disposed in the perforation, wherein an end of the push rod away from the pressing portion is partially exposed at the second open end;
wherein the push back button/key includes a non-metallic pad disposed between the pressing portion and the at least one button, and the non-metallic pad reaches the at least one button when the push back button/key is pressed.

18. The explosion-proof protective case according to claim 17, wherein a thickness of the non-metallic pad is between 0.5 mm and 10 mm.
